(19) United States
(12) Patent Application Publication
(10) Pub. No.: US 2024/0014287 A1
(43) Pub. Date: Jan. 11, 2024

(54) SEMICONDUCTOR DEVICE AND METHOD OF FABRICATING THE SAME

(71) Applicant: Samsung Electronics Co., Ltd., Suwon-si (KR)

(72) Inventors: Eunkyu LEE, Suwon-si (KR); Minsu SEOL, Suwon-si (KR); Keunwook SHIN, Suwon-si (KR)

(73) Assignee: Samsung Electronics Co., Ltd., Suwon-si (KR)

(21) Appl. No.: 18/338,869

(22) Filed: Jun. 21, 2023

(30) Foreign Application Priority Data
Jul. 11, 2022 (KR) 10-2022-0085267

(51) Int. Cl. H01L 29/51; H01L 29/78; H01L 29/423; H01L 29/49; H10B 12/00; H01L 29/40

(52) U.S. Cl. CPC H01L 29/513; H01L 29/7827; H01L 29/4236; H01L 29/4958; H01L 29/517; H10B 12/34; H01L 29/401

(57) ABSTRACT

A semiconductor device may include a substrate including a source area and a drain area separated by a trench; a gate insulating layer in the trench; and a gate electrode. The gate electrode may include a lower buried portion and an upper buried portion in the trench. The lower buried portion may include a first conductive layer, and the upper buried portion may include a two-dimensional (2D) material layer and a second conductive layer. The second conductive layer may include a transition metal. The first conductive layer may include a transition metal identical to the transition metal included in the second conductive layer. The 2D material layer may include a chalcogen compound of a transition metal which is identical to the transition metal in the second conductive layer.

### CROSS-REFERENCE TO RELATED APPLICATION

This application is based on and claims priority under 35 U.S.C. § 119 to Korean Patent Application No. 10-2022-0085267, filed on Jul. 11, 2022 in the Korean Intellectual Property Office, the disclosure of which is incorporated by reference herein in its entirety.

### BACKGROUND

### 1. Field

The disclosure relates to a semiconductor device and a method of manufacturing the semiconductor device.

### 2. Description of the Related Art

A transistor is a semiconductor device which may perform the function of electric switching and may be employed in various integrated circuit (IC) devices including a memory, a driving IC, a logic device, etc. To increase a degree of integration of an IC device, research has been conducted to develop a transistor having a reduced size while maintaining its performance.

Recently, a buried channel array transistor (BCAT) structure, which occupies less area and may be capable of securing sufficient effective distance, has been applied to dynamic random access memory (DRAM) products. The BCAT structure includes a structure in which a trench formed between a source area and a drain area of a substrate is filled with a gate electrode. As the gate electrode is buried in the trench formed between the source area and the drain area, a part of the gate electrode may overlap with the source area and the drain area.

In this case, as the degree of integration of the IC device increases, a gate insulating layer arranged between the gate electrode and the source and drain areas may be reduced, and accordingly, the gate induced drain leakage (GIDL) effect, by which charges charged in a capacitor (a cell capacitor of a memory) connected with the drain area are discharged, may occur, which may lead to performance degradation of a semiconductor device.

### SUMMARY

Provided are semiconductor devices having a structure in which a two-dimensional (2D) material layer is arranged in an upper area of a gate electrode adjacent to a source area and a drain area, and a method of manufacturing the semiconductor device.

Additional aspects will be set forth in part in the description which follows and, in part, will be apparent from the description, or may be learned by practice of the presented embodiments of the disclosure.

According to an example embodiment, a semiconductor device may include a substrate including a trench, a source area, and a drain area; a gate insulating layer in the trench; and a gate electrode in the trench. The source area and the drain may be spaced apart from each other with the trench between the source area and the drain area. The gate insulating layer may cover a lower surface of the trench and a sidewall of the trench. The gate electrode may include a lower buried portion and an upper buried portion in contact with the gate insulating layer. The lower buried portion may fill a lower area of the trench. The upper buried portion may be on the lower buried portion and may fill an upper area of the trench. The lower buried portion may include a first conductive layer. The first conductive layer may fill the lower area of the trench, and the first conductive layer may contact a side of the gate insulating layer and a lower area of a sidewall of the gate insulating layer. The upper buried portion may include a two-dimensional (2D) material layer and a second conductive layer. The 2D material layer may contact an upper area of the sidewall of the gate insulating layer in the trench. The second conductive layer may fill the upper area of the trench, and the second conductive layer may contact the 2D material layer and the first conductive layer. The second conductive layer may include a transition metal. The 2D material layer may include a chalcogen compound of a transition metal that may be identical to the transition metal in the second conductive layer.

In example embodiments, the first conductive layer may include a transition metal that may be identical to the transition metal included in the second conductive layer.

In example embodiments, the transition metal in the second conductive layer may include at least one of molybdenum (Mo), ruthenium (Ru), rhodium (Rh), titanium (Ti), cobalt (Co), tantalum (Ta), and tungsten (W).

In example embodiments, the 2D material layer may include at least one of sulfur (S), selenium (Se), and tellurium (Te).

In example embodiments, the semiconductor device may further include a capping layer on the gate electrode.

In example embodiments, the gate insulating layer may include a lower area surrounding the first conductive layer and an upper area surrounding the 2D material layer. The lower area may have a first permittivity. The upper area may have a second permittivity. The second permittivity may be less than the first permittivity.

In example embodiments, the gate insulating layer may include a lower area surrounding the first conductive layer and an upper area surrounding the 2D material layer. The lower area of the gate insulating layer may surround the first conductive layer and may have a first thickness. The upper area of the gate insulating layer may surround the 2D material layer and may have a second thickness. The second thickness may be greater than the first thickness.

In example embodiments, the 2D material layer may have an island form or may have a non-uniform thickness.

According to an example embodiment, a semiconductor device may include a substrate, a gate insulating layer, and a gate electrode. The substrate may include a trench, a source area, and a drain area. The source area and the drain area may be spaced apart from each other by the trench. The gate insulating layer may cover a lower surface of the trench and a sidewall of the trench. The gate electrode may be in the trench. The gate electrode may include a lower buried portion and an upper buried portion surrounded by the gate insulating layer. The lower buried portion may fill a lower area of the trench. The upper buried portion may be on the lower buried portion and may fill an upper area of the trench. The lower buried portion may include a first conductive layer. The first conductive layer may be surrounded by a side of the gate insulating layer and a lower area of a sidewall of the gate insulating layer. The upper buried portion may include a two-dimensional (2D) material layer and a second conductive layer. The 2D material layer may cover an upper surface of the first conductive layer and an upper area of the sidewall of the gate insulating layer. The second conductive layer may be surrounded by the 2D material layer. The first conductive layer and the second conductive layer may be spaced apart from each other with the 2D material layer therebetween. The second conductive layer may include a transition metal. The 2D material layer may include at least one of graphene, black phosphorus, amorphous boron nitride, 2D hexagonal boron nitride (h-BN), a chalcogen compound of a transition metal, and phosphorene.

In example embodiments, the transition metal of the second conductive layer may include at least one of molybdenum (Mo), ruthenium (Ru), rhodium (Rh), titanium (Ti), cobalt (Co), tantalum (Ta), and tungsten (W).

In example embodiments, the first conductive layer and the second conductive layer may include different transition metals.

In example embodiments, the 2D material layer may include at least one of sulfur (S), selenium (Se), and tellurium (Te).

In example embodiments, the semiconductor device may further include a capping layer on the gate electrode.

In example embodiments, the gate insulating layer may include a lower area surrounding the first conductive layer and an upper area surrounding the 2D material layer. The lower area may have a first permittivity. The upper area may have a second permittivity. The second permittivity may be less than the first permittivity.

In example embodiments, the gate insulating layer may include a lower area surrounding the first conductive layer and an upper area surrounding the 2D material layer. The lower area of the gate insulating layer may surround the first conductive layer and may have a first thickness. The upper area of the gate insulating layer may surround the 2D material layer and may have a second thickness. The second thickness may be greater than the first thickness.

In example embodiments, the 2D material layer may have an island form or may have a non-uniform thickness.

According to an example embodiment, a memory device may include a capacitor; and a semiconductor device electrically connected with the capacitor. The semiconductor device may include a substrate including a trench, a source area, and a drain area, the source area and the drain area being spaced apart from each other with trench between the source area and the drain area; a gate insulating layer covering a lower surface of the trench and a sidewall of the trench; and a gate electrode in the trench. The gate electrode may include a lower buried portion and an upper buried portion in contact with the gate insulating layer. The lower buried portion may fill a lower area of the trench. The upper buried portion may be on the lower buried portion and may contact the gate insulating layer. The upper buried portion may fill an upper area of the trench. The lower buried portion may include a first conductive layer. The first conductive layer may fill the lower area of the trench. The first conductive layer may contact a side of the gate insulating layer and a lower area of a sidewall of the gate insulating layer. The upper buried portion may include a two-dimensional (2D) material layer and a second conductive layer. The 2D material layer may contact an upper area of the sidewall of the gate insulating layer in the trench. The second conductive layer may fill the upper area of the trench. The second conductive layer may contact the 2D material layer and the first conductive layer. The second conductive layer may include a transition metal. The 2D material layer may include a chalcogen compound of a transition metal that may be identical to the transition metal included in the second conductive layer.

According to an example embodiment, a method of manufacturing a semiconductor device may include forming a trench in a substrate; forming a gate insulating layer covering a lower surface and a sidewall of the trench; forming a gate electrode filling the trench on the gate insulating layer; forming a capping layer on the gate electrode; and forming a source area and a drain area at each side of the gate electrode. The forming the gate electrode may include forming a first conductive layer, forming a two-dimensional (2D) material layer in the trench, and forming a second conductive layer. The first conductive layer may fill a lower area of the trench and may contact a side of the gate insulating layer and a lower area of a sidewall of the gate insulating layer. The 2D material layer may cover a part of an upper surface of the first conductive layer and the gate insulating layer in the trench, and the second conductive layer may fill an upper area of the trench. The second conductive layer may contact the 2D material layer and the first conductive layer. The second conductive layer may include a transition metal. The 2D material layer may include a chalcogen compound of a transition metal that is identical to the transition metal in the second conductive layer.

In example embodiments, the transition metal of the second conductive layer may include at least one of molybdenum (Mo), ruthenium (Ru), and rhodium (Rh).

In example embodiments, the first conductive layer and the second conductive layer may include a same transition metal.

In example embodiments, the 2D material layer may include at least one of sulfur (S), selenium (Se), and tellurium (Te).

In example embodiments, the gate insulating layer may include a lower area and an upper area. The lower area may surround the first conductive layer and may have a first permittivity. The upper area may surround the 2D material layer and may have a second permittivity. The second permittivity may be less than the first permittivity.

In example embodiments, the gate insulating layer may include a lower area and an upper area. The lower area of the gate insulating layer may surround the first conductive layer and may have a first thickness. The upper area of the gate insulating layer may surround the 2D material layer and may have a second thickness. The second thickness may be greater than the first thickness.

In example embodiments, the 2D material layer may have an island form or may have a non-uniform thickness.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1A is a cross-sectional view of a semiconductor device according to an embodiment;

FIG. 1B is a cross-sectional view of the semiconductor device of FIG. 1A taken along line A-A′;

FIG. 2 is a cross-sectional view of a semiconductor device according to another embodiment;

FIG. 3 is a cross-sectional view of a semiconductor device according to another embodiment;

FIG. 4 is a cross-sectional view of a semiconductor device according to another embodiment;

FIG. 5 is a diagram of configuration of a semiconductor device array according to an embodiment;

FIG. 6 is a cross-sectional view of a memory device according to an embodiment;

FIGS. 7A to 7G are cross-sectional views showing a method of manufacturing the semiconductor device according to an embodiment illustrated in FIG. 1 B; and

FIGS. 8A to 8G are cross-sectional views showing a method of manufacturing the semiconductor device according to an embodiment illustrated in FIG. 2.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

It will be understood that when a component is referred to as being “on” another component or on “upper part” of another component, the component can be directly on the other component or over the other component in a non-contact manner. As used herein, the singular forms “a,” “an” and “the” are intended to include the plural forms as well, unless the context clearly indicates otherwise. When a portion “includes” an element, another element may be further included, rather than excluding the existence of the other element, unless otherwise described.

The use of the terms “a,” “an,” and “the” and similar referents are to be construed to cover both the singular and the plural. The operations of all methods described herein can be performed in any suitable order unless otherwise indicated herein or otherwise clearly contradicted by context, and embodiments are not limited to the described order of the operations.

The connecting lines, or connectors shown in the various figures presented are intended to represent example functional relationships and/or physical or logical couplings between the various elements, and thus it should be noted that many alternative or additional functional relationships, physical connections or logical connections may be present in a practical device.

The use of any and all examples, or example languages provided herein, is intended merely to better illuminate embodiments and does not pose a limitation on the scope of embodiments unless otherwise claimed.

Hereinafter, a semiconductor device and a method of manufacturing the semiconductor device are described with reference to the attached drawings. In the drawings, like reference numerals in the drawings denote like elements, and sizes of components in the drawings may be exaggerated for clarity and convenience of explanation. Meanwhile, embodiments described below are provided merely as an example, and various modifications may be made from the embodiments.

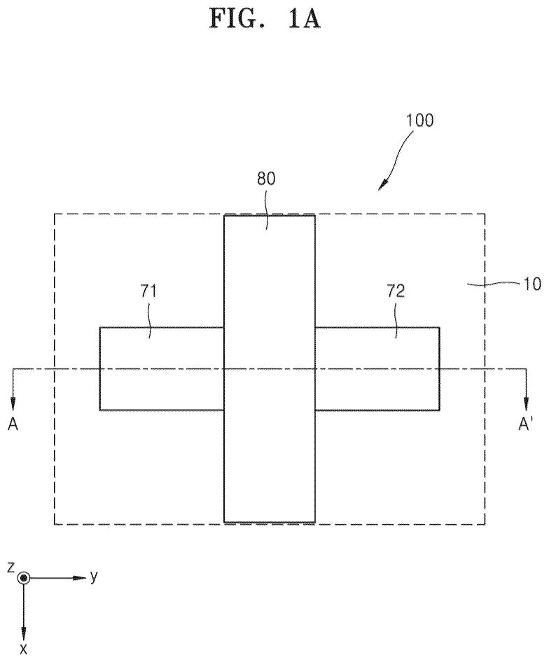

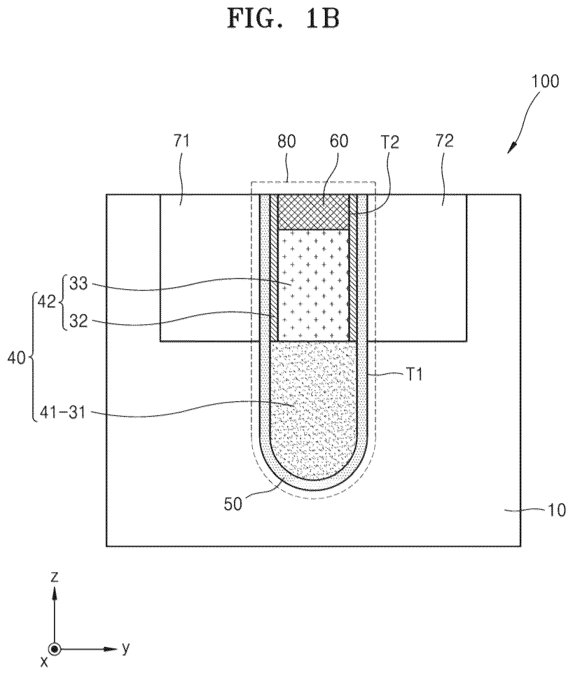

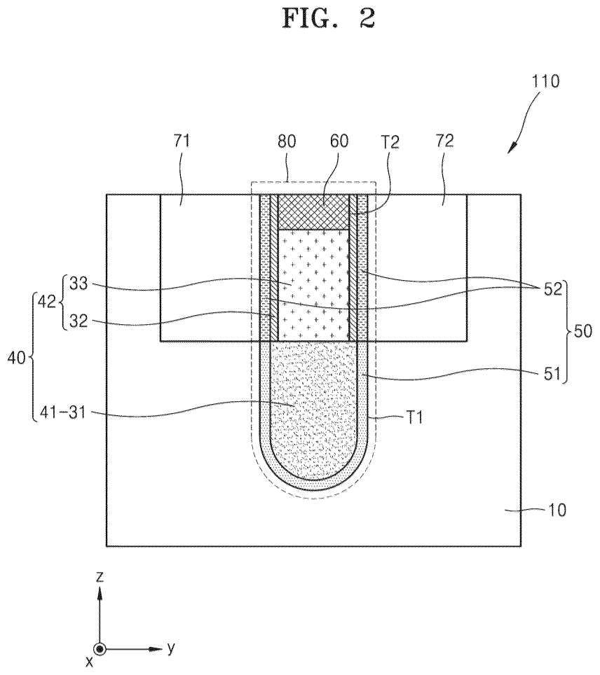

FIG. 1A is a cross-sectional view of a semiconductor device according to an embodiment, and FIG. 2 is a cross-sectional view of a semiconductor device according to another embodiment.

With reference to FIGS. 1A and 1B, a semiconductor device 100 may include a source area 71 and a drain area 72, which are arranged apart from each on a substrate 10, a trench T1 formed between the source area 71 and the drain area 72 on the substrate 10, a gate insulating layer 50 covering a lower surface and a sidewall of the trench T1, a gate electrode 40 including a lower buried portion 41 arranged in the trench T1 and in contact with the gate insulating layer 50 and filling a lower area of the trench T1 and an upper buried portion 42 arranged on the lower buried portion 41 and in contact with the gate insulating layer 50 and filling an upper area of the trench T1, and a capping layer 60 arranged on the gate electrode 40.

The substrate 10 may include a semiconductor substrate. The substrate 10 may include silicon, monocrystal silicon, polysilicon, amorphous silicon, silicon germanium, monocrystal silicon germanium, polycrystal silicon germanium, carbon-doped silicon, or a combination thereof. The substrate 10 may include a III/V group semiconductor substrate, for example, a compound semiconductor substrate, such as a gallium arsenic (GaAs) substrate.

The trench T1 may be formed by etching a part of the substrate 10 in the vertical direction (z direction) may be arranged in the substrate 10. The source area 71 and the drain area 72 may be spaced apart from each other in the horizontal direction (y direction) by the trench T1 may be arranged in the substrate 10. The source area 71 and the drain area 72 may be arranged side-by-side facing an upper area of the trench T1 in the horizontal direction (x and y directions). For example, an upper surface of the source area 71 and the drain area 72 and an upper surface of the substrate 10 may be arranged on the same plane. A lower surface of the source area 71 and the drain area 72 may be arranged higher than a lower surface of the trench T1. The source area 71 and the drain area 72 may be in contact with a sidewall of the trench Ti.

The source area 71 and the drain area 72 may be formed by doping a part of the substrate 10 with impurities. For example, the source area 71 and the drain area 72 may be formed by doping a part of the substrate 10 with any one of phosphorus (P), arsenic (As), antimony (Sb), and boron (B).

A gate structure 80 may be embedded in the trench Ti. The gate structure 80 may include the gate electrode 40, the gate insulating layer 50, and the capping layer 60. The gate electrode 40 may partially fill the inside of the trench T1. The gate insulating layer 50 may be arranged to be in contact with the lower surface and the sidewall of the trench Ti. The gate electrode 40 may partially fill the inside of the trench T1, and the gate insulating layer 50 may be arranged between the substrate 10 and the gate electrode 40 to surround the gate electrode 40. Accordingly, the gate electrode 40 may not be in direct contact with the lower surface and the sidewall of the trench Ti. The capping layer 60 may be arranged on the gate electrode 40.

The gate electrode 40 may include the lower buried portion 41 and the upper buried portion 42. The lower buried portion 41 may include a first conductive layer 31. The first conductive layer 31 may fill a lower area of the trench T1 and be arranged in the trench T1 and in contact with a lower surface and a sidewall of the gate insulating layer 50. In addition, as the lower buried portion 41 is arranged in the lower area of the inside of the trench T1, the lower buried portion 41 may not overlap with the source area 71 and the drain area 72, which are arranged parallel with the upper area of the trench T1, in the horizontal direction (x and y directions).

The first conductive layer 31 may include a transition metal material. For example, the first conductive layer 31 may include at least one of molybdenum (Mo), ruthenium (Ru), rhodium (Rh), titanium (Ti), cobalt (Co), tantalum (Ta), and tungsten (W). However, the disclosure is not limited thereto, and the first conductive layer 31 may include other transition metal materials, which may be deposited by an atomic layer deposition (ALD) method, in addition to molybdenum (Mo), ruthenium (Ru), rhodium (Rh), titanium (Ti), cobalt (Co), tantalum (Ta), and tungsten (W). The first conductive layer 31 may include a compound including a transition metal material.

The upper buried portion 42 may include a two-dimensional (2D) material layer 32 and a second conductive layer 33. The 2D material layer 32 may be arranged in the trench T1 and in contact with an upper area of the sidewall of the gate insulating layer 50. The second conductive layer 33 may fill the upper area of the trench T1 and be in contact with the 2D material layer 32 and the first conductive layer 31. For example, the second conductive layer 33 may partially fill the upper area of the trench T1, and the 2D material layer 32 may be arranged between the gate insulating layer and the second conductive layer 33 such that right and left sides of the second conductive layer 33 are in contact with the 2D material layer 32. Accordingly, the second conductive layer 33 may not be in contact with the gate insulating layer 50. The 2D material layer 32 may surround the second conductive layer 33 but leave an upper surface and a lower surface of the second conductive layer 33 uncovered. Accordingly, the upper surface and the lower surface of the second conductive layer 33 may not be in contact with the 2D material layer 32. The lower surface of the second conductive layer 33 may be in direct contact with the upper surface of the first conductive layer 31. In addition, as the upper buried portion 42 is arranged in the upper area of the inside of the trench T1, the lower buried portion 41 may overlap with the source area 71 and the drain area 72, which are arranged parallel with the upper area of the trench T1, in the horizontal direction (x and y directions). Accordingly, the 2D material layer 32 and the second conductive layer 33 may overlap with the source area 71 and the drain area 72 in the horizontal direction (x and y directions).

The 2D material layer 32 may include the same transition metal dichalcogenide as a transition metal of the second conductive layer 33. The 2D material layer 32 may include a transition metal element identical to the transition metal of the second conductive layer 33 and a chalcogen element selected from sulfur (S), selenium (Se), and tellurium (Te). The 2D material layer 32 may be in the form of an island or have a non-uniform thickness.

The second conductive layer 33 may include a transition metal. For example, the second conductive layer 33 may include a transition metal identical to the transition metal included in the first conductive layer 31. As the 2D material layer 32 includes a dichalcogenide of a transition metal identical to the transition metal of the second conductive layer 33, a work function of the gate electrode 40 may be reduced. Accordingly, a leakage current due to the gate induced drain leakage (GIDL) effect may be reduced. As the second conductive layer 33 includes a metal material, sufficient conductivity of the gate electrode 40 required to operate as a switching device may be secured. The capping layer 60 may be arranged on the upper surface of the second conductive layer 33. In this case, the 2D material layer 32 may extend to a lateral side of the capping layer 60. Accordingly, the lateral side of the capping layer 60 may be surrounded by the 2D material layer 32.

The gate insulating layer 50 may include a silicon oxide, a silicon nitride, a silicon oxynitride, a high-k material, or a combination thereof. The high-k material may include a material having a dielectric constant greater than that of a silicon oxide. For example, the high-k material may include a material having a dielectric constant greater than 3.9. In another example, the high-k material may include a material having a dielectric constant greater than 10. The high-k material may include at least one metallic element. The high-k material may include a hafnium-containing material. The hafnium-containing material may include a hafnium oxide, a hafnium silicon oxide, a hafnium silicon oxynitride, or a combination thereof. The high-k material may include a lanthanum oxide, a lanthanum aluminum oxide, a zirconium oxide, a zirconium silicon oxide, a zirconium silicon oxynitride, an aluminum oxide, or a combination thereof. Other known high-k materials may be used as the high-k material.

The capping layer 60 may include an insulating material. For example, the capping layer 60 may include a silicon nitride, a silicon oxynitride, or a combination thereof. Moreover, the capping layer 60 may include a combination of a silicon nitride and a silicon oxide. For example, the capping layer 60 may be formed through lining with silicon nitride and then filling with a spin on dielectric (SOD).

FIG. 2 is a cross-sectional view of a semiconductor device according to another embodiment.

A semiconductor device 110 of FIG. 2 may be substantially identical to the semiconductor device 100 of FIG. 1B except that the gate insulating layer 50 of the semiconductor device 110 may have different permittivities for each area. When describing FIG. 2, any redundant description with the description of FIGS. 1A and 1B may be omitted.

When the gate insulating layer 50 includes a silicon oxide, the gate insulating layer 50 may have different permittivities for each area. For example, a first permittivity (c1) of a lower area 51 of the gate insulating layer surrounding the first conductive layer 31 may be greater than a second permittivity (c2) of an upper area 52 of the gate insulating layer surrounding the 2D material layer 32. As the upper area 52 of the gate insulating layer may include a silicon oxycarbide, the upper area 52 may have a lower permittivity than that of the lower area 51 of the gate insulating layer, which only includes a silicon oxide. As such, compared to the case where the upper area 52 of the gate insulating layer has the first permittivity (c1) that is identical to the permittivity of the lower area 51, when the upper area 52 of the gate insulating layer has the second permittivity (c2), which is lower than the permittivity of the lower area 51, the capacitance between the upper buried portion 42 and the drain area 72 may decrease and the GIDL effect may be limited and/or minimized effectively.

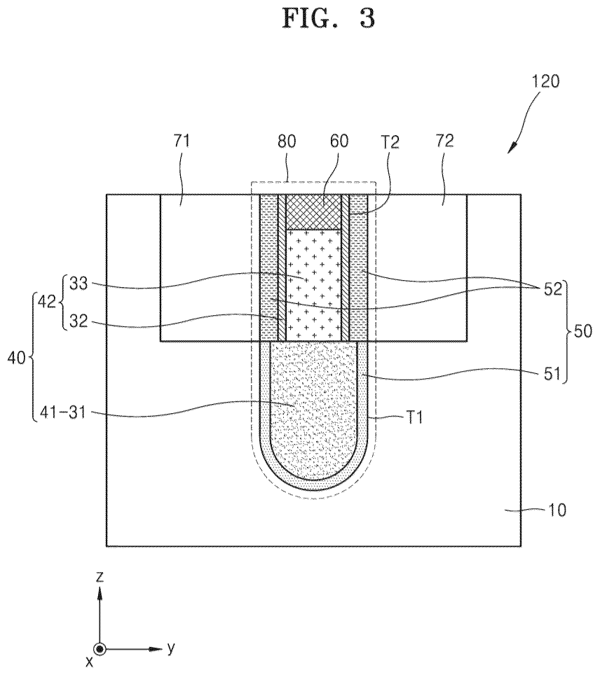

FIG. 3 is a cross-sectional view of a semiconductor device according to another embodiment.

A semiconductor device 120 of FIG. 3 may be substantially identical to the semiconductor device 100 of FIG. 1B except that the gate insulating layer 50 of the semiconductor device 120 may have different thicknesses for each area. When describing FIG. 3, any redundant description with the description of FIGS. 1A and 1B may be omitted.

With reference to FIG. 3, the gate insulating layer 50 may have different thicknesses for each area. For example, a first thickness of the lower area 51 of the gate insulating layer may be thinner than a second thickness of the upper area 52 of the gate insulating layer surrounding the 2D material layer 32. As such, compared to the case where the upper area 52 of the gate insulating layer has the first thickness that is identical to the thickness of the lower area 51, when the upper area 52 of the gate insulating layer has the second thickness, which is thicker than the thickness of the lower area 51, the capacitance between the upper buried portion 42 and the drain area 72 may decrease and the GIDL effect may be limited and/or minimized effectively. In addition, the thinner the lower area 51 of the gate insulating layer is, the wider the lower buried portion 41 may be, and the thicker the upper area 52 of the gate insulating layer is, the narrower the upper buried portion 42 may be.

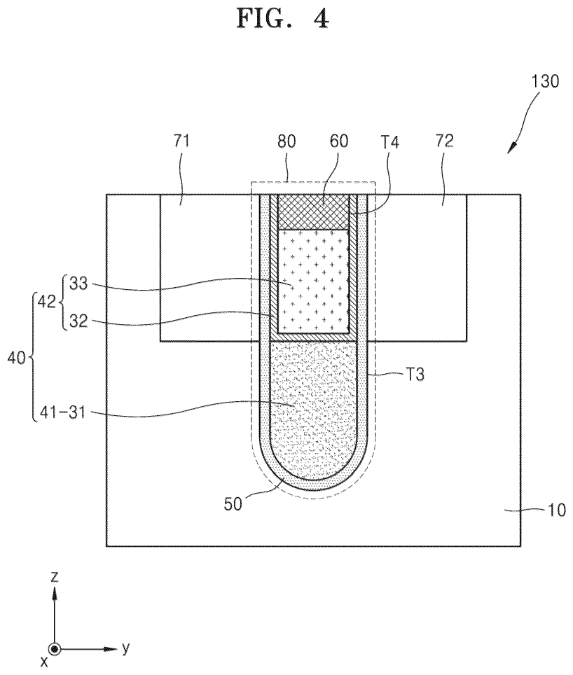

FIG. 4 is a cross-sectional view of a semiconductor device according to another embodiment.

A semiconductor device 130 of FIG. 4 may be substantially identical to the semiconductor device 100 of FIG. 1B except that the 2D material layer 32 of the semiconductor device 130 may include various 2D materials and that the 2D material layer 32 is provided at an interface between the first conductive layer 31 and the second conductive layer 33. When describing FIG. 4, any redundant description with the description of FIGS. 1A to 3 may be omitted.

With reference to FIG. 4, the semiconductor device 130 may include the source area 71 and the drain area 72, which are spaced apart from each other by the trench T1 in the substrate 10, the gate insulating layer 50 covering a lower surface and a sidewall of the trench T1, the gate electrode 40 including the lower buried portion 41 arranged in the trench T1, surrounded by the gate insulating layer 50 in the trench T1, and filling the lower area of the trench T1 and the upper buried portion 42 arranged on the lower buried portion 41, surrounded by the gate insulating layer 50, and filling the upper area of the trench T1, and the capping layer 60 arranged on the gate electrode 40.

The upper buried portion 42 may include the 2D material layer 32 and the second conductive layer 33. The 2D material layer 32 may be arranged in the trench T1 and in contact with an upper surface of the first conductive layer 31 and an upper area of a sidewall of the gate insulating layer 50. The 2D material layer 32 may cover the upper surface of the first conductive layer 31 and the upper area of the sidewall of the gate insulating layer 50. The 2D material layer 32 may surround the second conductive layer 33 and cover a lower surface of the second conductive layer 33. The first conductive layer 31 and the second conductive layer 33 may be spaced apart from each other by the 2D material layer 32. The 2D material layer 32 may be arranged between the first conductive layer 31 and the second conductive layer 33 and function as a barrier layer blocking a contact between the first conductive layer 31 and the second conductive layer 33. The second conductive layer 33 may be arranged to be surrounded by the 2D material layer 32 and the capping layer 60.

The 2D material layer 32 may include various 2D materials. For example, the 2D material layer 32 may include at least one of graphene, black phosphorus, an amorphous boron nitride, 2D h-BN, a chalcogen compound of a transition metal, and phosphorene. The chalcogen compound of a transition metal may include a chalcogen element selected from sulfur (s), selenium (Se), and tellurium (Te).

The second conductive layer 33 may include a transition metal material that is different from the transition metal included in the first conductive layer 31. The second conductive layer 33 may not be in contact with the first conductive layer 31. The second conductive layer 33 may be substantially identical to the second conductive layer 33 of FIG. 1B except that it may include a transition metal material that is different from the transition metal included in the first conductive layer 31 and that it may not be in contact with the first conductive layer 31.

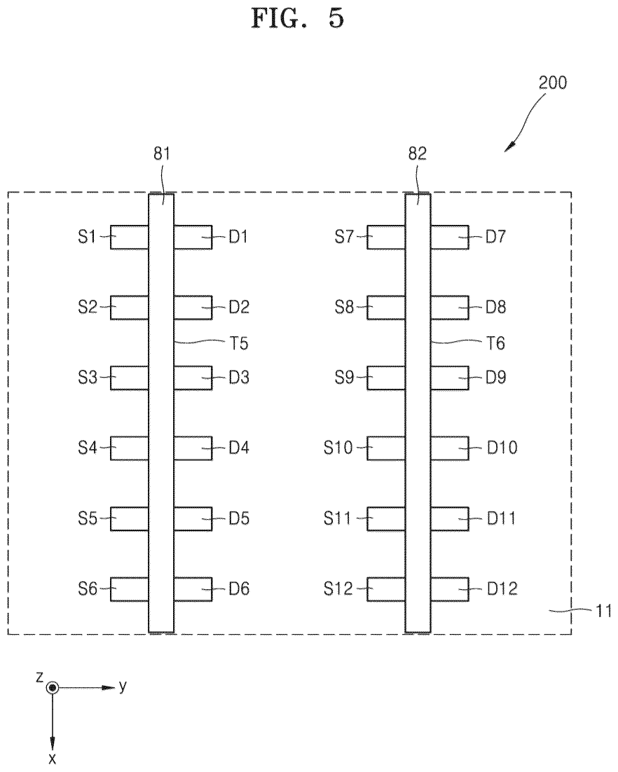

FIG. 5 is a diagram of configuration of a semiconductor device array according to an embodiment.

With reference to FIG. 5, a semiconductor device array 200 may include a substrate 11 including a plurality of trenches T5 and T6, a plurality of gate structures 81 and 82 respectively arranged at the plurality of trenches T5 and T6, a plurality of source areas S1 to S12 and a plurality of drain areas D1 to D12 respectively spaced apart from each other with the plurality of trenches T5 and T6 arranged therebetween.

The plurality of trenches T5 and T6 may be arranged apart from each other in a second direction (y direction) on the substrate 11, and extend parallel with each other in a first direction (x direction) intersecting with the second direction (y direction). The first direction (x direction) may be perpendicular to the second direction (y direction). Similar to the plurality of trenches T5 and T6, the plurality of gate structures 81 and 82 may be arranged apart from each other in the second direction (y direction) and extend parallel with each other in the first direction (x direction) intersecting with the second direction (y direction).

The plurality of source areas S1 to S6 may respectively face the plurality of drain areas D1 to D6, with the first gate structure 81 arranged therebetween. In addition, the plurality of source areas S7 to S12 may respectively face the plurality of drain areas D7 to D12, with the second gate structure 82 arranged therebetween. The first gate structure 81, the first source area S1 among the plurality of source areas S1 to S6, and the first drain area D1 among the plurality of drain areas D1 to D6, which face each other with the first gate structure 81 arranged therebetween, may form a first semiconductor device. The semiconductor device may include the semiconductor device (100, 110, 120, and 130) described with reference to FIGS. 1A to 4. As such, a plurality of semiconductor devices may be formed along each of the plurality of gate structures 81 and 82.

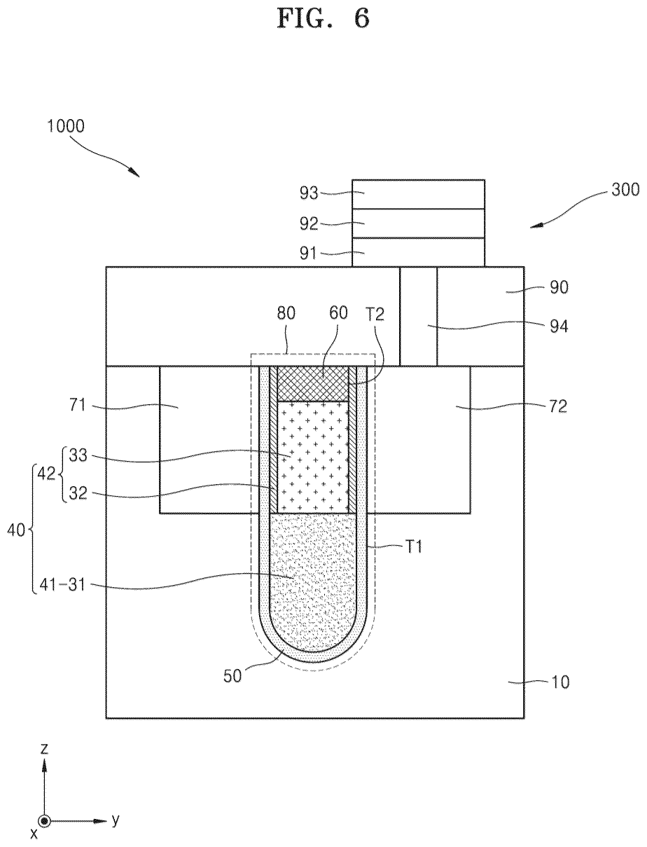

FIG. 6 is a cross-sectional view of a memory device according to an embodiment.

With reference to FIG. 6, a memory device 1000 may include the semiconductor device 100 and a capacitor 300. Although FIG. 6 illustrates that the memory device 1000 includes the semiconductor device 100 of FIG. 1 B, the memory device 1000 may include the semiconductor devices (110, 120, and 130) illustrated in FIGS. 2 to 4.

The memory device 1000 may include the source area 71 and the drain area 72 on the substrate 10 of the semiconductor device 100 and further include an interlayer insulating film 90 covering the gate structure 80. The interlayer insulating film 90 may include an insulating material.

The capacitor 300 may be arranged on the interlayer insulating film 90. The capacitor 300 may include a lower electrode 91 arranged on the interlayer insulating film 90, a dielectric layer 92 arranged on the lower electrode 91, and an upper electrode 93 arranged on the dielectric layer 92. The capacitor 300 may have a shape of a cylinder; however, the disclosure is not limited thereto, and in some embodiments, the capacitor 300 may have a shape of a pillar.

The lower electrode 91 and the upper electrode 93 may have various conductive materials. The lower electrode 91 and the upper electrode 93 may include, for example, at least one of polycrystal silicon, titanium nitride (TiN), tungsten (W), titanium (Ti), ruthenium (Ru), and tungsten nitride (WN). The dielectric layer 92 may include various insulating materials. The dielectric layer 92 may include, for example, at least one high-k material from zirconium oxide (ZrO₂), aluminum oxide (Al₂O₃), and hafnium oxide (Hf₂O₃).

A via hole may be formed in a partial area of the interlayer insulating film 90. The memory device 1000 may further include a contact 94 filled in the via hole. For example, the via hole may be formed to expose the drain area 72, and the contact 94 may be arranged in contact with the drain area 72. The capacitor 300 may be arranged on the interlayer insulating film 90 to be in contact with the contact 94. Accordingly, the capacitor 300 may be electrically connected with the drain area 72 through the contact 94. The shape and structure of the contact 94 may be changed, and the contact 94 may include various conductive materials.

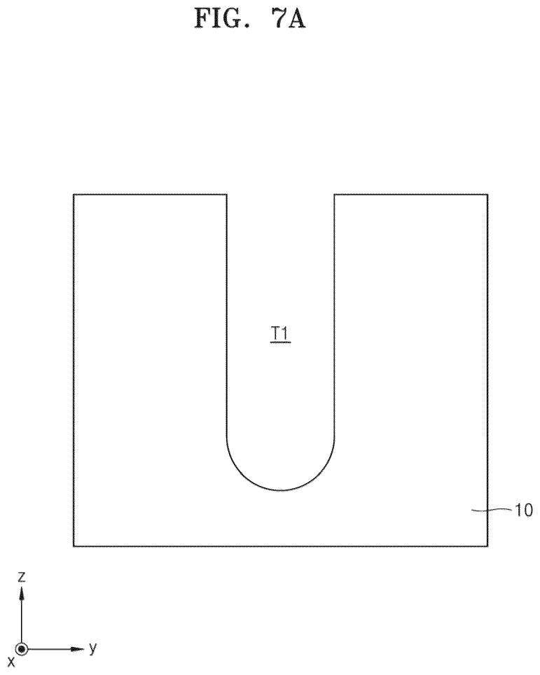

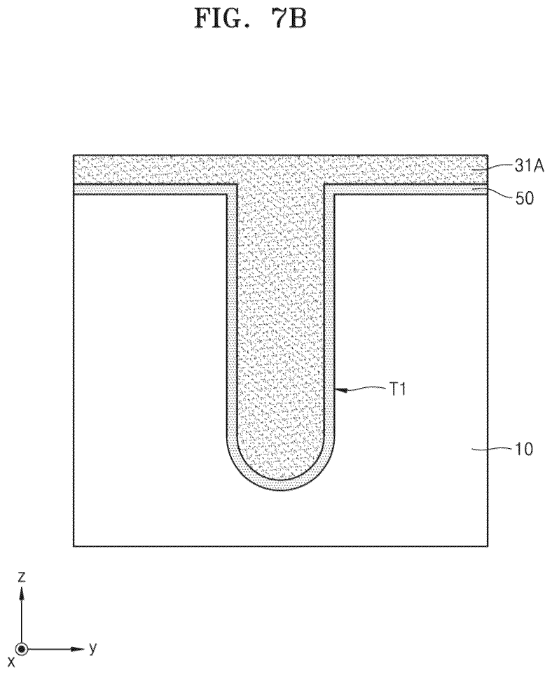

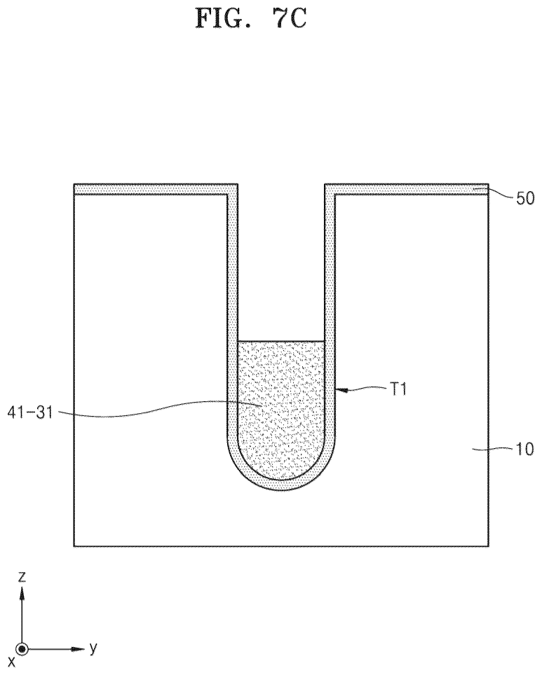

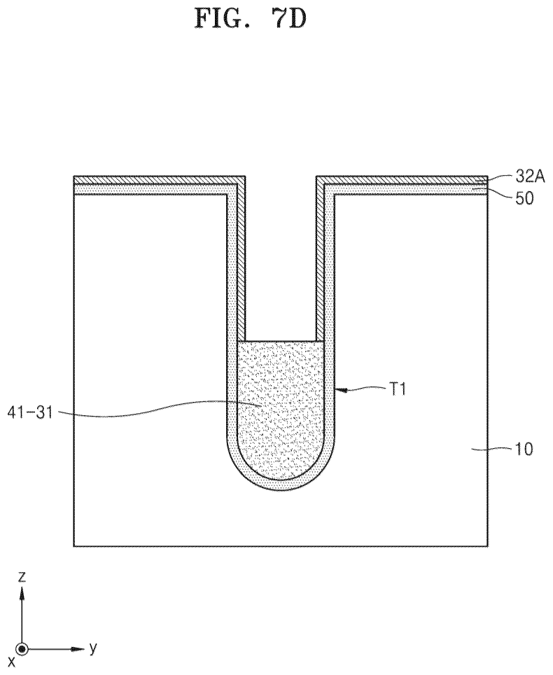

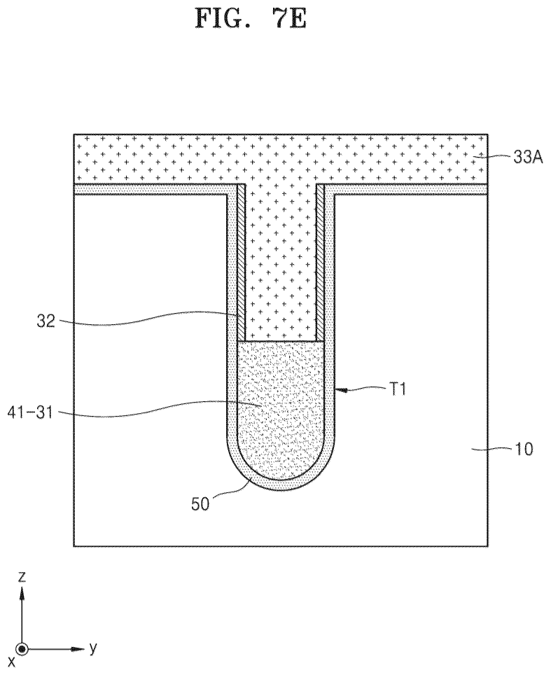

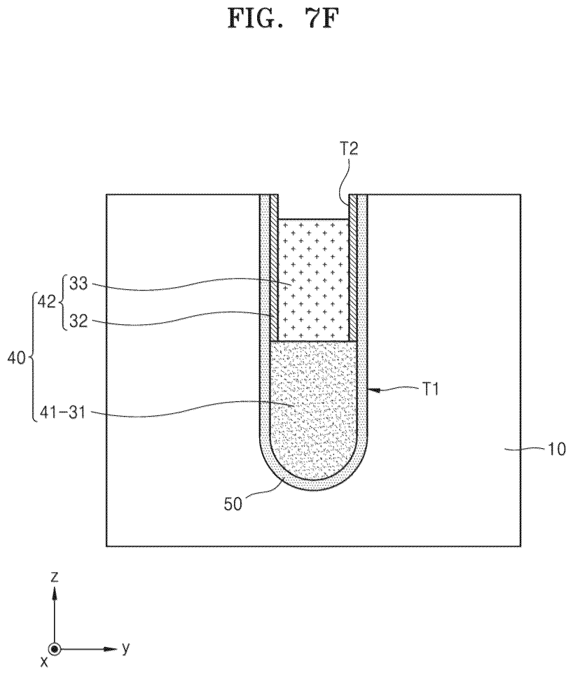

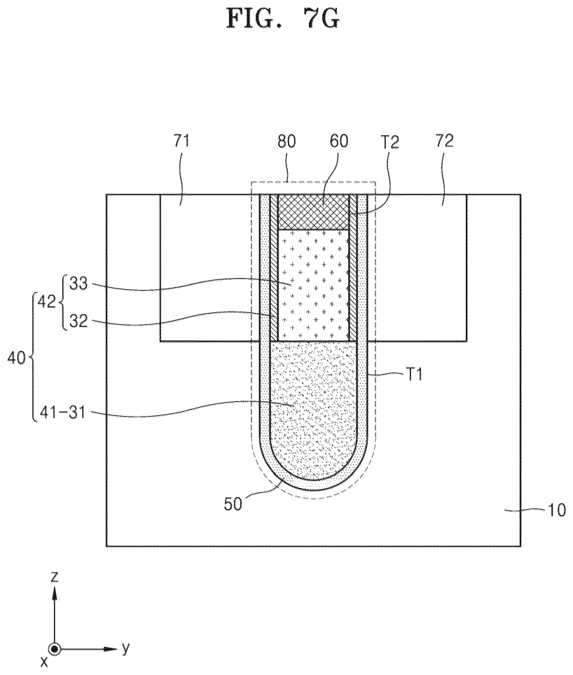

FIGS. 7A to 7G are cross-sectional views showing a method of manufacturing the semiconductor device according to an embodiment illustrated in FIG. 1B.

With reference to FIG. 7A, the trench T1 may be formed by patterning a part of the substrate 10.

With reference to FIG. 7B, the gate insulating layer 50 covering the lower surface and the sidewall of the trench T1 may be formed on the substrate 10. A first preliminary conductive layer 31A filling the trench T1 may be formed on the gate insulating layer 50.

With reference to FIG. 7C, the lower buried portion 41, which is in contact with the lower area of the sidewall of the gate insulating layer 50 in the trench T1, may be formed by patterning the first preliminary conductive layer 31A. The lower buried portion 41 may include the first conductive layer 31 filling the lower area of the trench T1 and in contact with the lower surface and the lower area of the sidewall of the gate insulating layer 50.

With reference to FIG. 7D, a preliminary 2D material layer 32A covering a part of the upper surface of the first conductive layer 31 and the gate insulating layer 50 may be formed. The preliminary 2D material layer 32A may be formed by using an ALD method.

With reference to FIG. 7E, by patterning the preliminary 2D material layer 32A, the 2D material layer 32 which is in contact with the part of the upper surface of the first conductive layer 31 and the upper area of the sidewall of the gate insulating layer 50 may be formed. In addition, a second preliminary conductive layer 33A filling the upper area of the trench T1 may be formed on the gate insulating layer 50.

With reference to FIG. 7F, by patterning the second preliminary conductive layer 33A, the second conductive layer 33 partially filling the upper area of the trench T1 and in contact with the 2D material layer 32 and the first conductive layer 31 may be formed. For example, the upper surface of the second conductive layer 33 may be lower than the upper surface of the substrate 10. Accordingly, a capping layer trench T2 exposing a part of the gate insulating layer 50 may be formed. Moreover, in the process of patterning the second preliminary conductive layer 33A, a part of the gate insulating layer 50 arranged on the upper surface of the substrate 10 may also be patterned.

With reference to FIG. 7G, the capping layer 60 filling the capping layer trench T2 may be formed.

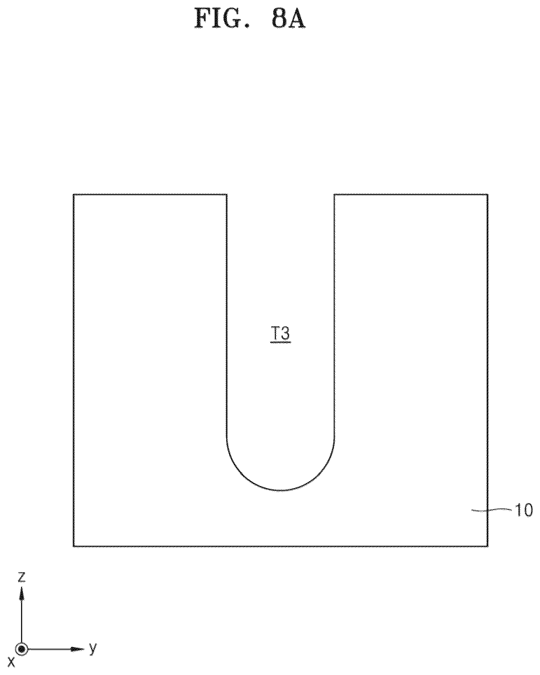

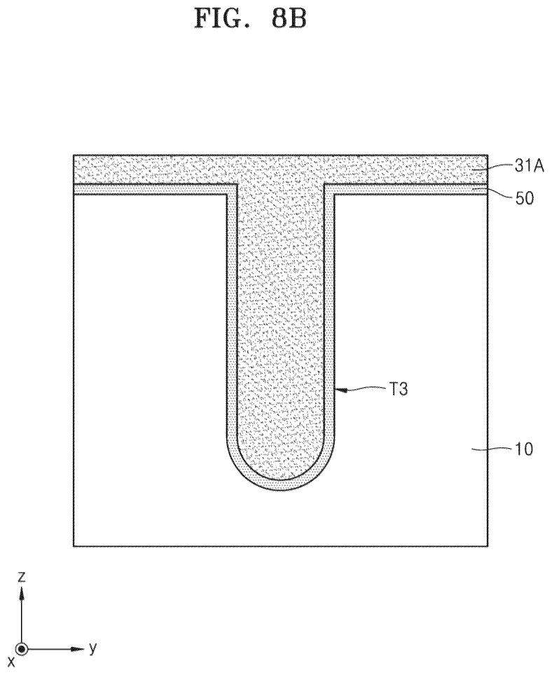

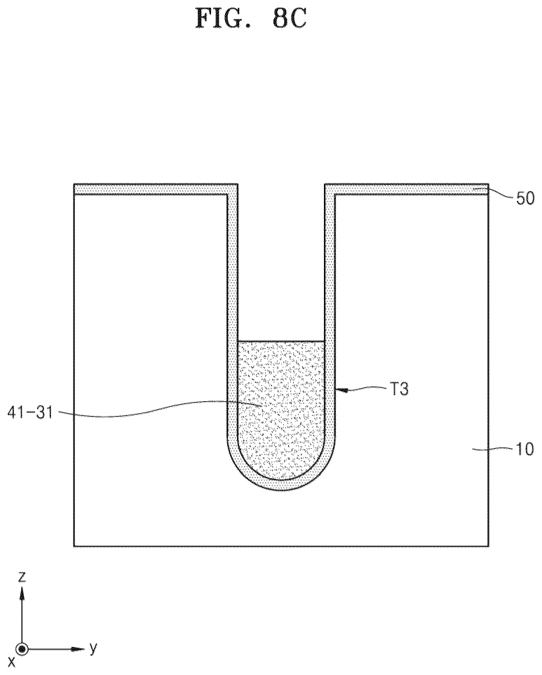

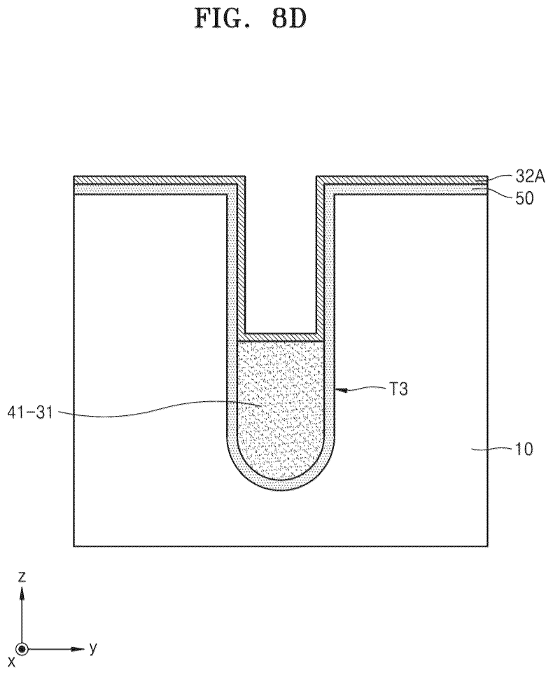

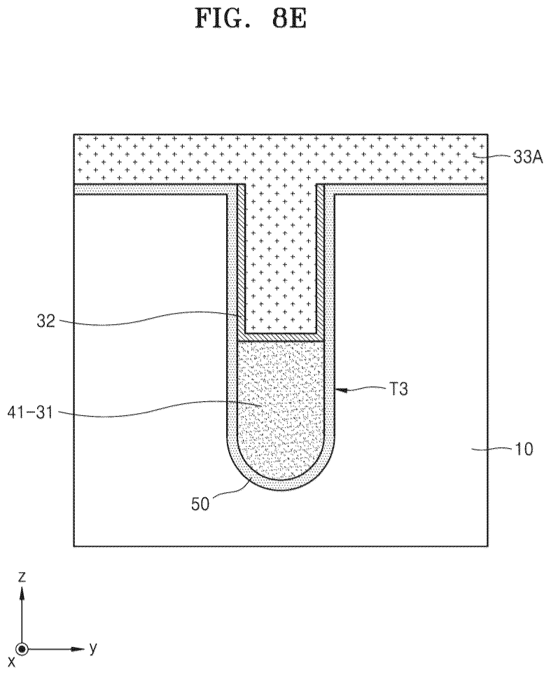

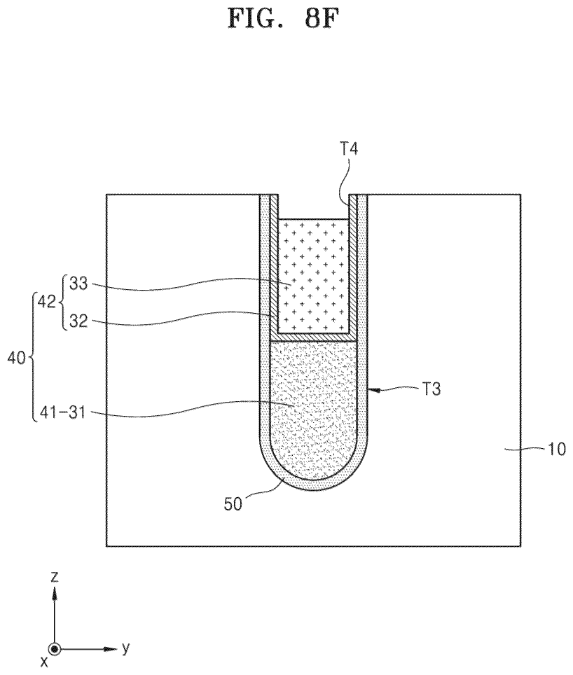

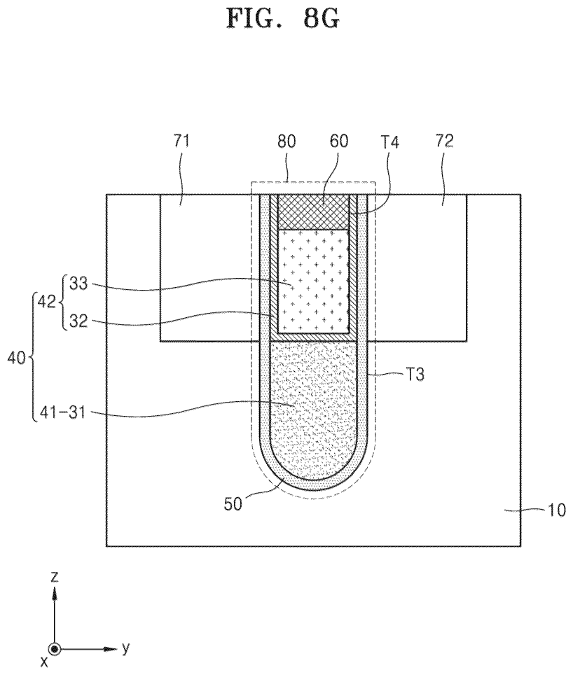

FIGS. 8A to 8G are cross-sectional views showing a method of manufacturing the semiconductor device according to an embodiment illustrated in FIG. 4.

With reference to FIG. 8A, a trench T3 may be formed by patterning a part of the substrate 10.

With reference to FIG. 8B, the gate insulating layer 50 covering the lower surface and the sidewall of the trench T3 may be formed on the substrate 10. A first preliminary conductive layer 31A filling the trench T3 may be formed on the gate insulating layer 50.

With reference to FIG. 8C, the lower buried portion 41, which is in contact with the lower area of the sidewall of the gate insulating layer 50 in the trench T3, may be formed by patterning the first preliminary conductive layer 31A. The lower buried portion 41 may include the first conductive layer 31 filling the lower area of the trench T3.

With reference to FIG. 8D, the preliminary 2D material layer 32A, which is in contact with the upper surface of the first conductive layer 31 and the upper area of the sidewall of the gate insulating layer 50, may be formed. The preliminary 2D material layer 32A may be formed by using an ALD method.

With reference to FIG. 8E, by patterning the preliminary 2D material layer 32A, the 2D material layer 32 which is in contact with the upper surface of the first conductive layer 31 and the upper area of the sidewall of the gate insulating layer 50 may be formed. In addition, a second preliminary conductive layer 33A filling the upper area of the trench T3 may be formed on the gate insulating layer 50.

With reference to FIG. 8F, by patterning the second preliminary conductive layer 33A, the second conductive layer 33 partially filling the upper area of the trench T3 and surrounded by the 2D material layer 32 may be formed. For example, the upper surface of the second conductive layer 33 may be lower than the upper surface of the substrate 10. Accordingly, a capping layer trench T4 exposing a part of the gate insulating layer 50 may be formed. Moreover, in the process of patterning the second preliminary conductive layer 33A, a part of the gate insulating layer 50 arranged on the upper surface of the substrate 10 may also be patterned.

With reference to FIG. 8G, the capping layer 60 filling the capping layer trench T4 may be formed.

According to embodiments of inventive concepts in the present disclosure, a semiconductor device with reduced leakage current and improved word line conductivity may be provided.

The semiconductor device according to the presented embodiments may have reduced leakage current and may secure the word line conductivity.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of inventive concepts as defined by the following claims.

What is claimed is:

1. A semiconductor device comprising:
a substrate including a trench, a source area, and a drain area,
the source area and the drain area being spaced apart from each other with the trench between the source area and the drain area;
a gate insulating layer covering a lower surface of the trench and a sidewall of the trench; and
a gate electrode in the trench,
the gate electrode including a lower buried portion and an upper buried portion in contact with the gate insulating layer,
the lower buried portion filling a lower area of the trench, and
the upper buried portion on the lower buried portion and filling an upper area of the trench,
the lower buried portion including a first conductive layer, the first conductive layer filling the lower area of the trench, and the first conductive layer contacting a side of the gate insulating layer and a lower area of a sidewall of the gate insulating layer,
the upper buried portion including a two-dimensional (2D) material layer and a second conductive layer, the 2D material layer contacting an upper area of the sidewall of the gate insulating layer in the trench, the second conductive layer filling the upper area of the trench, and the second conductive layer contacting the 2D material layer and the first conductive layer,
the second conductive layer including a transition metal, and
the 2D material layer including a chalcogen compound of a transition metal that is identical to the transition metal in the second conductive layer.

2. The semiconductor device of claim 1, wherein the first conductive layer includes a transition metal that is identical to the transition metal in the second conductive layer.

3. The semiconductor device of claim 1, wherein the transition metal in the second conductive layer includes at least one of molybdenum (Mo), ruthenium (Ru), rhodium (Rh), titanium (Ti), cobalt (Co), tantalum (Ta), and tungsten (W).

4. The semiconductor device of claim 1, wherein the 2D material layer includes at least one of sulfur (S), selenium (Se), and tellurium (Te).

5. The semiconductor device of claim 1, further comprising:
a capping layer on the gate electrode.

6. The semiconductor device of claim 1, wherein
the gate insulating layer includes a lower area surrounding the first conductive layer and an upper area surrounding the 2D material layer,
the lower area has a first permittivity, and
the upper area has a second permittivity that is less than the first permittivity.

7. The semiconductor device of claim 1, wherein
the gate insulating layer includes a lower area and an upper area,
the lower area of the gate insulating layer surrounds the first conductive layer and has a first thickness,
the upper area of the gate insulating layer surrounds the 2D material layer and has a second thickness, and
the second thickness is greater than the first thickness.

8. The semiconductor device of claim 1, wherein the 2D material layer in has an island form or has a non-uniform thickness.

9. A semiconductor device comprising:
a substrate including a trench, a source area, and a drain area,
the source area and the drain area being spaced apart from each other by the trench;
a gate insulating layer covering a lower surface of the trench and a sidewall of the trench; and
a gate electrode in the trench,
the gate electrode including a lower buried portion and an upper buried portion surrounded by the gate insulating layer,
the lower buried portion filling a lower area of the trench,
the upper buried portion on the lower buried portion and filling an upper area of the trench,
the lower buried portion including a first conductive layer, the first conductive layer being surrounded by a side of the gate insulating layer and a lower area of a sidewall of the gate insulating layer,
the upper buried portion including a two-dimensional (2D) material layer and a second conductive layer, the 2D material layer covering an upper surface of the first conductive layer and an upper area of the sidewall of the gate insulating layer, and the second conductive layer being surrounded by the 2D material layer,
the first conductive layer and the second conductive layer being spaced apart from each other with the 2D material layer therebetween,
the second conductive layer including a transition metal, and
the 2D material layer including at least one of graphene, black phosphorus, amorphous boron nitride, 2D hexagonal boron nitride (h-BN), a chalcogen compound of a transition metal, and phosphorene.

10. The semiconductor device of claim 9, wherein the first conductive layer and the second conductive layer include different transition metals.

11. The semiconductor device of claim 9, wherein
the gate insulating layer includes a lower area surrounding the first conductive layer and an upper area surrounding the 2D material layer,
the lower area of the gate insulating layer has a first permittivity,
the upper area has a second permittivity, and
the second permittivity is less than the first permittivity.

12. The semiconductor device of claim 9, wherein
the gate insulating layer includes a lower area surrounding the first conductive layer and an upper area surrounding the 2D material layer,
the lower area has a first thickness,
the upper area has a second thickness, and
the second thickness is greater than the first thickness.

13. The semiconductor device of claim 9, wherein the 2D material layer in has an island form or has a non-uniform thickness.

14. A memory device comprising:
a capacitor; and
the semiconductor device of claim 1 electrically connected with the capacitor.

15. A method of manufacturing a semiconductor device, the method comprising:
forming a trench in a substrate;
forming a gate insulating layer covering a lower surface and a sidewall of the trench;
forming a gate electrode filling the trench on the gate insulating layer;
forming a capping layer on the gate electrode; and
forming a source area and a drain area at each side of the gate electrode,
wherein the forming the gate electrode includes
forming a first conductive layer, the first conductive layer filling a lower area of the trench and contacting a side of the gate insulating layer and a lower area of a sidewall of the gate insulating layer,
forming a two-dimensional (2D) material layer in the trench, the 2D material layer covering a part of an upper surface of the first conductive layer and the gate insulating layer in the trench, and
forming a second conductive layer, the second conductive layer filling an upper area of the trench,
wherein
the second conductive layer contacts the 2D material layer and the first conductive layer,
the second conductive layer includes a transition metal, and
the 2D material layer includes a chalcogen compound of a transition metal that is identical to the transition metal in the second conductive layer.

16. The method of claim 15, wherein the transition metal of the second conductive layer includes at least one of molybdenum (Mo), ruthenium (Ru), and rhodium (Rh).

17. The method of claim 15, wherein the first conductive layer and the second conductive layer include a same transition metal.

18. The method of claim 15, wherein
the gate insulating layer includes a lower area and an upper area,
the lower area surrounds the first conductive layer and has a first permittivity,
the upper area surrounds the 2D material layer and has a second permittivity, and
the second permittivity is less than the first permittivity.

19. The method of claim 15, wherein
the gate insulating layer includes a lower area and an upper area,
the lower area of the gate insulating layer surrounds the first conductive layer and has a first thickness,
the upper area of the gate insulating layer surrounds the 2D material layer and has a second thickness, and
the second thickness is greater than the first thickness. The method of claim 15, wherein the 2D material layer has an island form or has a non-uniform thickness.
